(19) United States
(12) Patent Application Publication
(10) Pub. No.: US 2016/0313370 A1
(43) Pub. Date: Oct. 27, 2016

(54) SEMICONDUCTOR DEVICE TESTER WITH DUT DATA STREAMING

(71) Applicant: INTEL CORPORATION, Santa Clara, CA (US)

(72) Inventors: James Neeb, Gilbert, AZ (US); Vineet Pancholi, Chandler, AZ (US); Gerard McSweeney, Chandler, AZ (US); Shelby Rollins, Hillsboro, OR (US); Chris Johnson, Hillsboro, OR (US); Nathan Blackwell, Hillsboro, OR (US); Bradly L. Inman, Hillsboro, OR (US); Steven Lill, Chandler, AZ (US); Rodney J. Christner, Phoenix, AZ (US); Phillip Barnes, Chandler, AZ (US)

(21) Appl. No.: 14/655,684

(22) PCT Filed: Jul. 28, 2014
(86) PCT No.: PCT/US2014/048509

§ 371 Date: Jun. 25, 2015

(51) Int. Cl. G01R 1/02; G01R 31/28; G01R 29/26

(52) U.S. Cl. CPC G01R 1/025; G01R 29/26; G01R 31/2896

(57) ABSTRACT

A method is described that includes configuring multiple test units of a semiconductor device tester with respective information indicating respective storage space within either or both of an off load processing unit and central control unit of the tester. The method further includes streaming DUT data from the test units to their respective storage space within at least one of the off load processing unit and the central control unit such that the test units continually initiate the sending of their respective DUT data to their respective storage space.

### FIELD OF INVENTION

The field of invention pertains generally to semiconductor device testing and more specifically to a semiconductor device tester with DUT data streaming.

### BACKGROUND

The testing of semiconductor devices is a standard component of the numerous processes that are performed to manufacture and deliver working semiconductor device products. The testing of semiconductor devices presents various challenges. As such, tester technology is continually advancing to achieve higher throughput, more accurate/refined testing results, and better reliability.

### BRIEF DESCRIPTION OF THE DRAWINGS

FIG. 1 shows a prior art test system;

FIG. 2 shows an improved test system;

FIG. 3 shows a first methodology performed by the test system;

FIG. 4 shows a second methodology performed by the test system.

### DETAILED DESCRIPTION

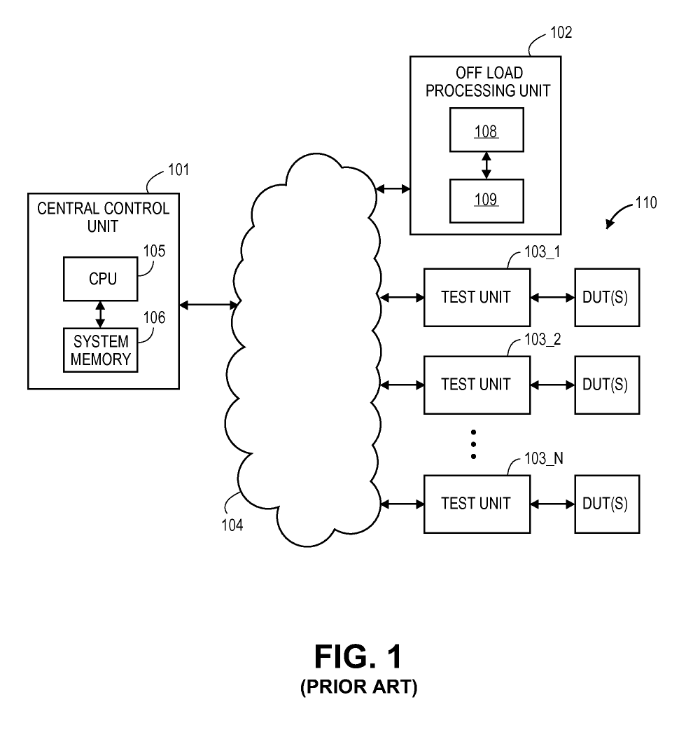

FIG. 1 shows a prior art test apparatus. As observed in FIG. 1 the prior art test apparatus includes a central control unit 101, an off-load processing unit 102, a plurality of test units 103_1 through 103_N and a communication network 104.

The central control unit 101 is implemented as a computing system (e.g., a personal computer) having a central processing unit (CPU) 105 and system memory 106 for executing software. The installed software on the central control unit 101 includes a testing operating system 106 and testing application software programs 107.

The off-load processing unit 102 includes computation hardware 108 (e.g., an application specific integrated circuit (ASIC), field programmable gate array (FPGA), digital signal processor (DSP) or general purpose processor (GPP)) and/or software and/or firmware coupled with data storage resources 109 (e.g., registers and/or memory) to perform various post processing tasks on test data generated from one or more of the test units 103_1 through 103_N. Some of these tasks include: 1) calculating device under test (DUT) power consumption from measured DUT current drawn data; 2) determining whether DUT thresholds have been exceeded (e.g., from determined DUT power consumption and measured DUT temperature); 3) determining DUT error rates; 4) FFT's on sampled data. The central control unit 101 and/or off load processing unit 102 also initiates logging of the test information (e.g., recording test data records to deeper storage).

Each of the test units 103_1 through 103_N include hardware logic and/or a software designed to perform various testing functions directly to/from the DUTs 110 in response to commands from the central control unit 101 or the off-load processor 102. For example, each test unit 103_1 through 103_N is typically coupled to a plurality of DUTs and performs one of more of the following functions: 1) applies a supply voltage to its DUTs; 2) applies various input signals (e.g., digital input data patterns, clock signals, etc.) to it DUTs; 3) receives various signals (e.g., digital output patterns) from its DUTs; 4) measures electrical current drawn by its DUTs; 5) measures the (e.g., case and/or ambient) temperature of its DUTs; 6) measures voltage(s) provided by the DUTs. The DUTs may be packaged or unpackaged semiconductor chip dice.

The communication network 104 interconnects the test units 103_1 through 103_N to the central control unit 101 and the off-load processor unit 102. The communication network is implemented as a Peripheral Component Interface Express (PCIe) interconnect but conceivably other communication network technologies can be used (e.g., Universal Serial Bus (USB)).

A problem with the prior art tester of FIG. 1 is that the transportation of measured data from the test units 103_1 through 103_N to the central control unit 101 or the off-load processor unit 102 is cumbersome. More, specifically, the system is designed such that both the off-load processing unit 102 and each of the test units 103_1 through 103_N are operable as slaves to the central control unit 101 which is regarded as the master.

As such, the transportation of data collected by any of the test units to the central control unit 101 or the off-load processor unit 102 requires the intervention and set-up and control of the transaction by the central control unit 101. Said another way, the central control unit 101 oversees and controls the scheduling of the transportation of the test data from any of the test units 103_1 through 103_N to either the central control unit 101 or off load processing unit 102. As a consequence, the transportation of data includes substantial overhead within network 104.

Even more specifically, the central control unit 101 first sends a command to a particular test unit to send a specific unit of data to either the central control unit 101 or the off-load processing unit 102. The test unit then sends the data. In the case of data being sent to the off-load processing unit 102, the off-load processing unit sends confirmation to the central control unit 101 that the data has been successfully received and/or the central control 101 sends a command to the off-load processor 102 to prepare to receive the data from the test unit. The back-and-forth communication between the central control unit 101 and the test unit and off-load processor 102 imposes a significant amount of overhead traffic on network which “slows down” the overall operation of the tester to the point where “real time” tracking of the DUTs is not possible.

Because real time tracking of DUTs is not possible, the tester's reliability is at risk. More specifically, because of the overall slowness of the system (owing to the above described overhead traffic) considerable time lapses before current and/or temperature data measured from a particular DUT is actually processed by the central control unit 101 or the off-load control unit 102. As such, if a particular DUT is exhibiting signs of failure, realization of the same does not happen until much later in time. In the case of sudden, catastrophic failures in which the DUT (or more than one DUT) essentially becomes a short circuit, the detection of the short circuit may not be detected in time to shut-down the test unit. As such, the test unit may be damaged, and potentially other components of the tester and/or other DUTs.

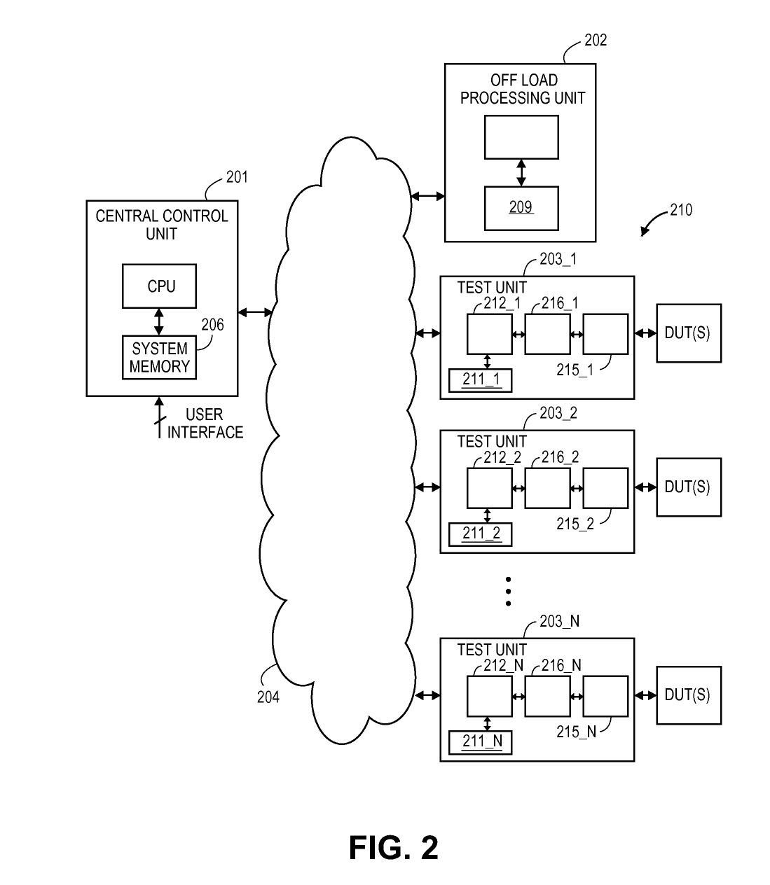

FIG. 2 depicts an improved tester design. As observed in FIG. 2, each of the test units 203_1 through 203_N have been enhanced to include the functionality to send their data directly to the central control unit 201 and/or the off load processing unit 202 without an initial command from the central control unit 201. Thus, the test units 203_1 through 203_N have been designed to autonomously “stream” their data into the central control unit 201 and/or the off load processing unit 202 in a direct-memory-access (DMA) like fashion.

By having the authority to initiate transfers to either or both of the central control unit 201 and the off load processing unit 202, the overhead traffic that transpires over network 204 is greatly reduced. As such, the time-latency bottleneck that previously existed between the collection of the data and the moment it could be processed and comprehended is greatly reduced resulting in near “real-time” observation and understanding of the DUTs 210.

According to one embodiment, upon initialization of the test system (e.g., during initial bring-up or boot-up), each test unit is informed of the unique storage space that has been allocated for it within the central control unit 201 and the within the off load processing unit 202. That is, test unit 201_1 is allocated specific storage space within central control unit 201 and off load processing unit 202, test unit 202_2 is allocated specific, different storage space within central control unit 201 and off load processing unit 202. In an embodiment, the respective storage space that is allocated to the different test units do not overlap such that each test unit essentially has its own dedicated storage space within both the central control unit 201 and the off load processing unit 202 to send its measured data to.

In a further embodiment, the dedicated storage space is specified with an address range. For example, each test unit is provided with a unique address range of system memory 206 within central control unit 201 and a unique address range of register space and/or memory space 209 within off-load processing unit 202. Thus, during initialization each test unit is informed of its dedicated address ranges for later reference (e.g., by one or more initialization packets sent from the central control unit 201 during the initialization process).

In an embodiment, each test unit 203_1 through 203_N has its own respective configuration space 211_1 through 211_N (e.g., register space and/or memory space) where its allocated address range information is written to during initialization and kept during testing operations. Over the course of testing, this information is utilized to forward test data to the correct higher level destination. More specifically, in an embodiment, a test unit will create a packet having a payload portion that contains measured test data and a header portion that contains an address within the address range allotted to the particular test unit for the particular destination (an address within the address range of the central control unit system memory if the packet is being sent to the central control unit, or, an address within the address range of the off load processing unit if the packet is being sent to the off load processing unit).

As observed in FIG. 2, each test unit has specially designed hardware, firmware and/or software 215_1 through 215_N to execute the specific tasks associated with applying voltages and/or signals to DUTs and receiving output signals/voltages from DUTs. Each test unit has memory 216_1 through 216_N into which the measured data is buffered. Each test unit has a controller 217_1 through 217_N that has access to and comprehends the target address space that has been configured in the test unit's configuration space and controls the sending of packets to such target address space with data that is buffered in memory 216.

In a further embodiment, each test unit is effectively provided with a “time slice” of the bandwidth of network 204 and repeatedly transmits its respective packets within its reserved time slice. Here, in an implementation, a test unit will transmit a packet of test data to the off load processor every 2 milliseconds (ms) and will transmit a packet of test data to the central control unit every 4 ms. Having information from a particular DUT (or group of DUTs) sent to the central control unit and/or off load processing unit continually updated at this frequency permits the “real time” data analysis that the prior art test system was not capable of performing Notably, the central control unit 201 is configured to receive less overall data from a particular test unit than the off load processing unit 202. Hence the test unit sends information less frequently to the central control unit 201.

According to one approach, the test system runs synchronously through network 204 with each of the central control unit 201, off load processing unit 202 and the test units 203_1 through 203_N able to comprehend same time slot windows. Each test unit is then configured (e.g., by the central control unit 201 during initialization of the system) with its respective broadcast time slot windows for transmission of data packets to the central control unit and the off load processing unit. During run-time the test units comprehend a system master clock and when the system master clock corresponds to their allotted time slot window for transmission. The time slots may be correlated with periodic measurements applied by the test units to their corresponding DUTs.

In alternate embodiments the test units transmit test data information in an ad hoc fashion without any predetermined window time slot configuration or any other higher order organization. According to one ad hoc approach, packets are not actually sent until an earlier request_to_send message is sent from a test unit to the intended destination and responded to favorably. According to another ad hoc approach, a request_to_send message is not even sent and packets are just launched into the network 204 on an optimistic basis. Even in an ad hoc approach, however, attempted transmissions may be periodic. In an ad hoc approach, the central control unit 201 and the off load processor 202 may include contention logic to handle multiple requests from multiple test units that concurrently arrive.

With each of the test units 203_1 through 203_N having an understanding of the storage resource addresses where their data will be stored within the central control unit and/or the off load processing unit, each of the test units themselves may adjust the target address in the packet header information (incrementing the target address with each new packet of information). That is, the test unit themselves can calculate based on how much information they are sending when to increment up to a next address value for inclusion in a packet header. The test unit may also be designed to “rollover” to the starting address of its allocated space once the last address of the allocated space has been written. Here, there is an understanding that the old data will be flushed (e.g., to deeper storage) or written over and lost.

The test data typically includes one or more of the following: 1) a measured current drawn by a DUT; 2) a measured associated temperature of a DUT; 3) a digital output signal of a DUT; 4) a voltage level applied to a DUT; and, 5) a voltage level provided by a DUT. A timestamp of each measurement can also be included with each measurement so that “when” the specific data item was measured is also recorded.

Some test units may be designed to measure the radio frequency (RF) characteristics of the DUTs. Here, many semiconductor chips contain radio circuitry for wireless communications. The radio circuitry typically contains “RF” components near the antenna for processing high frequency signals at or about the carrier signal frequencies at which the radio communications occur. The test unit may therefore be designed to apply a wireless radio signal to a DUT, receive a wireless radio signal from a DUT, test a “noise floor” of the DUT along a ground plane or power plane, etc. Such data can be processed, e.g., by the off load signal processor, to determine various RF characteristics of a DUT (e.g., signal quality, signal-to-noise ratio, etc.).

With near real-time data analysis being performed by the central control unit 201 or the off load processing unit 202 a number of significant advances are realizable above and beyond the prior art system of FIG. 1.

Most significantly, DUTs that are exhibiting catastrophic failure symptoms can be detected in time to send a high priority command to the DUT's test unit to shut down the DUT before it degrades into a short circuit or other electrical danger that could damage the test equipment. For example, if current being drawn by a particular DUT begins to ramp-up (e.g., beyond a threshold) the off-load processor can detect the same and command the DUT's test unit to cease application of a supply voltage to the DUT.

Alternatively or in combination, the off-load processor can perform calculations from the data that measure critical parameters of the DUTs in real time. For example, for a DUT that corresponds to a packaged die, the temperature of the die can be calculated from the measured ambient and/or case temperature of the die's package and/or the power consumption of the die (the power consumption of the die can, in turn, be calculated from the voltage applied to the die, the clock frequency applied to the die and/or the current drawn from the die). Critical breakdown regions of devices can therefore be predicted from, e.g., a combination of the calculated die temperature and/or the calculated die's power consumption. Thus, again, the off-load processor can intervene to shut down testing of DUT before the DUT actually breaks down in time to save the test equipment from damage.

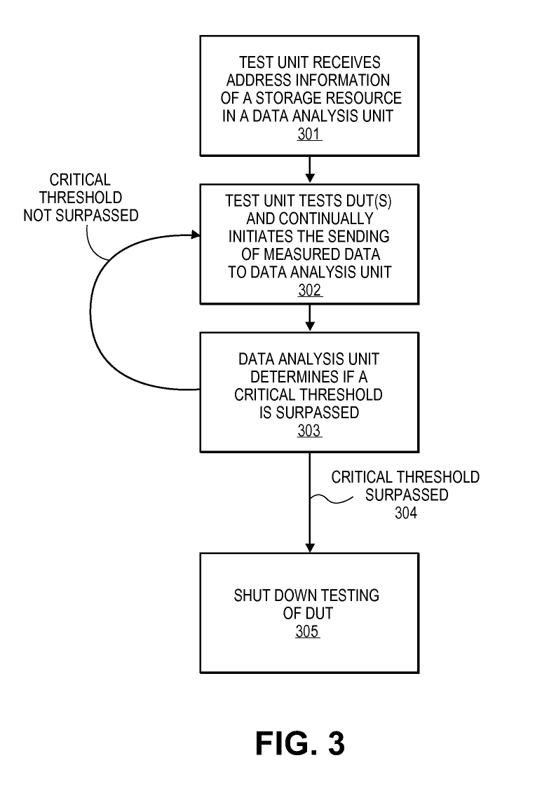

FIG. 3 shows a process performed by the tester that is capable of detecting failures in quasi real time. As observed in FIG. 3, a test unit of the tester receives 301 address information (e.g., an address range, a starting address, etc.) of a storage resource (e.g., memory, register space, non-volatile storage, etc.) within a data analysis unit (e.g., a resource capable of analyzing the data such as the central control unit 201 or the off-load processor 202).

The test unit then begins testing one or more DUTs and continually initiates the sending of the measured data from its DUTs to the data analysis unit for storage in the data analysis unit 302. As discussed above, the nature of the transmissions can be akin to a DMA in which, e.g., the test unit comprehends and adjusts the targeted address for storage accordingly as the data continues to be transmitted.

The data analysis unit then monitors the data in quasi real-time including, potentially, performing calculations on the data (e.g., power consumption, die temperature) to determine if a critical threshold has been surpassed 303. If a critical threshold of any DUT is surpassed 304, the data analysis unit causes further testing of the DUT to be shut down 305 so that damage to the tester can be avoided.

Another pertinent improvement of the new tester design is that any of the measured data or calculations can be provided to the central control unit 201 for practically real-time graphical display through a graphical user interface (GUI). The prior art tester of FIG. 1 imposed too much latency between the moment the data was measured and the moment the data was available for display. With the improved ability to upload measured data in a DMA like fashion to the central control unit's memory, updates to the central control unit memory for any particular DUTs data permit that DUTs data to be visually displayed, e.g., through a GUI, in a quasi-real time manner (e.g., less than 10 ms after the data is actually measured by the test unit).

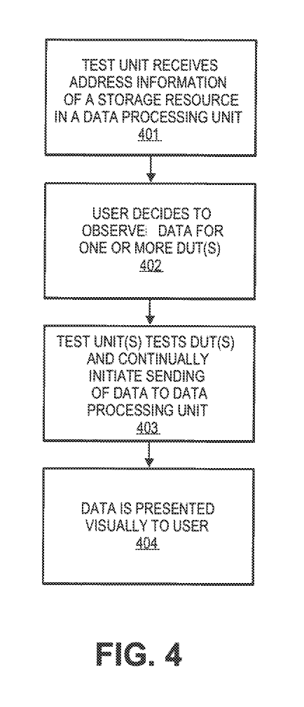

FIG. 4 shows a process performed by the tester that is capable of visually presenting measured data (e.g., graphically through a GUI) in quasi real time. As observed in FIG. 4, a test unit of the tester receives 401 address information (e.g., an address range, a starting address, etc.) of a storage resource (e.g., memory, register space, non-volatile storage, etc.) within a data processing unit (e.g., a resource capable of processing the data such as the central control unit 201 or the off load processing unit 202) having some form of user interface (e.g., a touch-screen, a keyboard and display, etc.).

A user indicates 402 through the user interface that the user desires to see data for a specific one or more DUTs and/or see information processed from such data (e.g., power consumption of the DUT, die temperature of the DUT, etc.).

One or more test units then begin testing the one or more DUTs and continually initiate the sending of the measured data from its DUTs to the data processing unit for storage in the data processing unit 403. As discussed above, the nature of the transmissions can be akin to a DMA in which, e.g., each test unit comprehends and adjusts the targeted address for storage accordingly as the data continues to be transmitted.

The data is then presented to the user visually 404 (or processed and the results thereof presented to the user), e.g., as a graph on a display through a GUI. Note that the timestamp information appended to each data measurement allows for easy rendering of DUT data as a function of time.

Any of the processes taught by the discussion above may be performed with software, hardware logic circuitry or some combination thereof. It is believed that processes taught by the discussion above may also be described in source level program code in various object-orientated or non-object-orientated computer programming languages. An article of manufacture may be used to store program code. An article of manufacture that stores program code may be embodied as, but is not limited to, one or more memories (e.g., one or more flash memories, random access memories (static, dynamic or other)), optical disks, CD-ROMs, DVD ROMs, EPROMs, EEPROMs, magnetic or optical cards or other type of machine-readable media suitable for storing electronic instructions. Program code may also be downloaded from a remote computer (e.g., a server) to a requesting computer (e.g., a client) by way of data signals embodied in a propagation medium (e.g., via a communication link (e.g., a network connection)).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method, comprising:
configuring multiple test units of a semiconductor device tester with respective information indicating respective storage space within either or both of an off load processing unit and central control unit of said tester;
streaming DUT data from said test units to their respective storage space within at least one of said off load processing unit and said central control unit such that said test units continually initiate the sending of their respective DUT data to their respective storage space.

2. The method of claim 1 wherein the data is streamed to the off load processing unit and the off load processing unit performs calculations on the data.

3. The method of claim 2 wherein the calculations include DUT power consumption.

4. The method of claim 2 wherein the calculations include a DUT breakdown parametric.

5. The method of claim 4 wherein further testing of said DUT is stopped in response to save parametric having been exceeded a threshold.

6. The method of claim 1 wherein the data for a particular DUT is streamed to the central control unit from the DUT's respective test unit in response to a user requesting a visual display of data pertaining to a particular DUT.

7. The method of claim 6 wherein the display is a graphical display of the DUT's data through a graphical user interface.

8. The method of claim 6 wherein the display of data is graphical display of information calculated from the DUT data.

9. A machine readable medium containing program code that when processed by a processing unit of a test unit of a semiconductor device tester causes the processing unit of the test unit to perform a method, comprising:
receiving configuration information indicating respective storage space within either or both of an off load processing unit and central control unit of said tester;
streaming data from said test unit to the respective storage space within at least one of said off load processing unit and said central control unit such that said test unit continually initiates the sending of DUT data to the respective storage space.

10. The machine readable medium of claim 9 wherein the data is streamed to the off load processing unit and the off load processing unit performs calculations on the data.

11. The machine readable medium of claim 10 wherein the method further comprises receiving a command to stop testing of the DUT.

12. The machine readable medium of claim 9 wherein the method of further comprises receiving a request from the central control unit for data for a particular DUT.

13. The machine readable medium of claim 9 wherein the method further comprises streaming data of the DUT to the central control unit.

14. A semiconductor device tester, comprising:
a central control unit;
an off-load processing unit;
a network between the central control unit and the off load processing unit;
a plurality of test units, each test unit having configuration space to hold information indicative of storage space within at least one of said central control unit and said off-load processing unit, said each test unit having a controller to stream DUT data to said storage space such that said controller initiates transmission of said DUT data to said storage space.

15. The semiconductor device tester of claim 14 wherein said controller initiates transmission on a periodic basis.

16. The semiconductor device tester of claim 14 wherein said periodic basis includes initiating transmission at less than 10 ms intervals.

17. The semiconductor device tester of claim 14 wherein said off-load processing unit includes processing hardware and software to determine from streamed DUT data whether a DUT is in danger of suffering a breakdown and causing further testing of said DUT to be stopped in response to said determination.

18. The semiconductor device tester of claim 14 wherein said central control unit graphically displays streamed DUT data, or information calculated therefrom, through a graphical user interface.
